(19) United States
(12) Patent Application Publication
(10) Pub. No.: US 2008/0223299 A1
(43) Pub. Date: Sep. 18, 2008

(54) SYSTEM FOR DETECTING PLASMA REACTION AND METHOD FOR USING THE SAME

(76) Inventors: Cheng-Jer Yang, Taoyuan County (TW); Shu-Ching Yang, Taoyuan County (TW); Hong-Ming Chang, Hsinchu County (TW); Hung-Wen Chiou, Hsinchu City (TW)

Correspondence Address: HOLLAND & KNIGHT LLP, 10 ST. JAMES AVENUE, 11th Floor, BOSTON, MA, 02116-3889, US

(21) Appl. No.: 11/839,976

(22) Filed: Aug. 16, 2007

(30) Foreign Application Priority Data
Mar. 16, 2007 (TW) 096109099

(51) Int. Cl. H01L 21/306; B05C 11/00; G01N 37/00

(52) U.S. Cl. 118/712; 156/345.24; 73/28.02

(57) ABSTRACT

A system for detecting a plasma reaction and a method for using the same are provided. When the plasma reaction changes its reaction power, a lightness variation accompanies the power change. The system comprises a sensing device with a resistance that the resistance of the sensing device will be changed in response to the lightness variation; thereby the system can detect the status of the plasma reaction.

This application claims the benefit of priority based on Taiwan Patent Application No. 096109099 filed on Mar. 16, 2007, and the disclosures of which are incorporated herein by reference in their entirety.

### CROSS-REFERENCES TO RELATED APPLICATIONS

Not applicable.

### BACKGROUND OF THE INVENTION

1. Field of the Invention

The subject invention relates to a monitoring device and a monitoring method for a manufacturing process; the invention especially relates to a monitoring system and a monitoring method for detecting a plasma reaction.

2. Descriptions of the Related Art

Plasma is one of the greatest discoveries in modern physical chemistry. When gas molecules are ionized into particles, such as ions with positive or negative charges, electrons, and radicals, in an electric field, the mixture of these particles is so called plasma.

Plasma is in widespread use in the semiconductor manufacturing process, such as in the manufacturing process of thin film deposition, dry etching, and ion implantation. It is essential to monitor the plasma reaction in the manufacturing process precisely and instantaneously.

In a plasma reaction, a plurality of particles are excited and thus are in the excited status. After energies of secondary electrons are captured by these particles in the electric field, these energies can be released in manners of light waves and accompany a unique glow phenomenon. The frequency of the light wave spreads between zones of visible light and ultraviolet.

According to the abovementioned, two prior methods of monitoring the plasma reaction are used. The first one method uses a mechanism of monitoring parameters generated by equipment. The other uses an optic emission spectrum sensor. In more details, the former uses parameters generated by built-in plasma glow equipment as monitoring references. For example, a forward voltage and a reverse voltage are usually used to confirm whether the plasma reaction glows or not. In some real applications, however, the plasma does not react and glow while the forward voltage and the reverse voltage indicate the reaction is conducted normally. Therefore, a monitoring error is occurred and the yield of the manufacturing process degrades.

On the other hand, the optic emission spectrum sensor is used to detect the status and the features of the plasma reaction by detecting the variation of compositions of plasma. Though the accuracy of this method is very high, this optic emission spectrum sensor is hard to be adopted because it costs several millions. It is too expensive to be in widespread use in semiconductor manufacturing processes. Moreover, optical fibers must be used to transmit light wave when the optic emission spectrum sensor operates. The optical fiber is fragile and easily damaged. It is necessary to replace the damaged optical fiber as it was bent by external force. The maintenance of the whole monitoring equipment is not easy. Furthermore, the optic emission spectrum sensor is an external sensor. It is hard to integrate the sensor into the original manufacturing equipment for reaction data collection.

Therefore, it is essential to improve the conventional system and method for monitoring plasma reaction effectively and be easily adopted in all kinds of plasma manufacturing processes.

### SUMMARY OF THE INVENTION

One objective of the subject invention is to provide a system for detecting a plasma reaction. When the plasma reaction has a power variation, a lightness variation accompanies the power variation. The system comprises a sensing device, which comprises a resistance, wherein the resistance will be changed in response to the lightness variation; thereby the system can detect the status of the plasma reaction.

Another objective of the subject invention is to provide a method for detecting a plasma reaction. When the plasma reaction has a power variation, a lightness variation accompanies the power variation. The method comprises: providing a sensing device, the sensing device comprising a resistance; changing the resistance in response to the lightness variation; measuring the resistance of the sensing device; and generating a signal in response to the resistance.

The detailed technology and preferred embodiments implemented for the subject invention are described in the following paragraphs accompanying the appended figures for people skilled in this field to well appreciate the features of the claimed invention.

### BRIEF DESCRIPTION OF THE DRAWINGS

FIG. 1 depicts an exemplary embodiment of a system for detecting a plasma reaction of the subject invention;

FIG. 2A depicts an exemplary embodiment of power variations in plasma reactions;

FIG. 2B depicts an exemplary embodiment of resistance variations of the sensing device corresponding to FIG. 2A; and

FIG. 2C depicts one of the curves shown in FIG. 2B.

### DESCRIPTION OF THE PREFERRED EMBODIMENT

According to the abovementioned disadvantages of the prior plasma reaction detecting system, the subject invention develops a new system for detecting a plasma reaction for accurately and precisely detecting the variation of a plasma reaction. The cost of manufacturing the detecting system can be significantly reduced. It would be beneficial for widespread use in all kinds of plasma manufacturing processes.

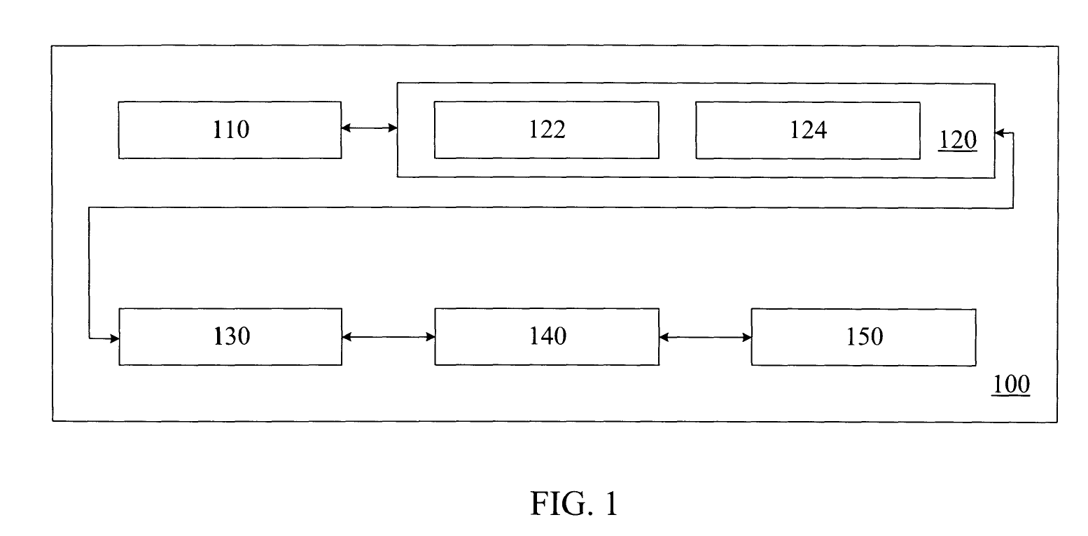

Please refer to FIG. 1, which schematically illustrates a system 100 for detecting a plasma reaction in one embodiment of the subject invention. The detection system of the subject invention can be easily adopted in many reactions, such as thin film deposition, dry etching, ion implantation, and so forth, which are conducted in a plasma reaction chamber (not shown). According to the above-mention, in a plasma reaction, a power variation accompanies a lightness variation. The detection system 100 disclosed by the subject invention utilizes the feature of the lightness variation to instantaneously and precisely detect the variation of the plasma reaction as further described hereinafter.

The system 100 for detecting a plasma reaction mainly comprises a sensing device 110 which comprises a resistance. The sensing device 110 would change its resistance in response to the lightness variation of a plasma reaction in a visible light zone. The purpose of instantaneously monitoring the plasma reaction can be made by measuring the resistance variation of the sensing device 110. In a preferred embodiment, the sensing device 110 can be, for example, but not limited to a photoconductive resistance. One of the features of the photoconductive resistance is that the resistance thereof will increase or decrease in response to the lightness variation. Specifically, the photoconductive resistance is CdS. The cost of CdS is very cheap so that the total cost for constructing the whole detection system of the subject invention can be significantly reduced. Compared with the optic emission spectrum sensor of the prior art, it is much easier to adopt the detection system of the subject invention to semiconductor manufacturing processes.

In a preferred embodiment, the detection system for a plasma reaction of the subject invention can be integrated into the present manufacturing equipment to facilitate users to monitor the whole plasma reaction by using the detecting signals. Specifically, referring to FIG. 1, the detection system 100 for a plasma reaction of the subject invention further comprises a signal processing device 120, a signal transmission module 130, a database 140 and an error detection device 150.

The signal processing device 120 electrically connects to the sensing device 110. The signal processing device 120 is used to generate a signal in response to the resistance of the sensing device 110 and to process the signal after measuring the resistance. In a real application, common cables can be used to connect the signal processing device 120 and the sensing device 110 rather than using optical fibers as connection means. In view of the material cost and the maintenance, the cables adopted by the subject invention provide advantages of curving randomly, hard to be damaged and low costs.

Specifically, the sensing device 110 of the invention is directly affixed to the external surface of the observation window of the plasma reaction chamber. Specially, the resistance value of the photoconductive resistance made by CdS would be affected by the contact condition between the photoconductive resistance and the observation window. Accordingly, when the photoconductive resistances of the subject invention are used in a plurality of the monitoring systems of plasma reaction equipment, it is hard to monitor a plurality of plasma reactions with a standard if each photoconductive resistance has a different output voltage. Therefore, it is essential to adjust each of the output voltages of the signals generated by sensing devices 110 in order to effectively monitor each of the plasma reaction equipment to which the sensing devices 110 are affixed. Specifically, the signal processing device 120 comprises an offset circuit assembly 122 used for adjusting the output voltage of the signal, generated by measuring the resistance of the sensing device 110, so that the output voltage of the signal would has an identical standard. Consequently, the output voltages of a plurality of sensing device 110 belonged to different plasma reaction equipment would be controlled in a voltage range as a monitoring range to facilitate the central monitoring system to control different plasma reactions simultaneously. For example, a level of 5 volts will be set as the initial output voltage of the sensing device 110 before the plasma does not begin to react. On the other hand, a level of zero volts will be set as the output voltage of the sensing device 110 when the plasma has a maximum power.

Next, in a real application, the voltage signal generated by the signal processing device 120 measuring the sensing device 110 is an analog signal. The signal processing device 120 further comprises a signal converter 124 used for converting the analog signal to a digital signal to facilitate the process of the signal. Moreover, the signal transmission module 130 of the detection system 100 for plasma reaction of the subject invention electrically connects with the signal processing device 120 and the database 140. The signal transmission module 130 is used to transmit the signal processed by the signal processing device 120 to the database 140. In real applications, depending on the type of the plasma reaction equipment, a proper signal transmission module 130 would be selected, such as an RS232 module or a TCPIP module.

In addition, the database 140 would store the signal processed by the signal processing device 120 via the signal transmission module 130. The database 140 further electrically connects to an error detection device 150 to provide the abovementioned monitoring range for a plasma reaction to the error detection device 150. When the indicated parameters of the plasma reaction are over the monitoring range, a simultaneous warning alert would be provided to increase the yield of the manufacturing processes.

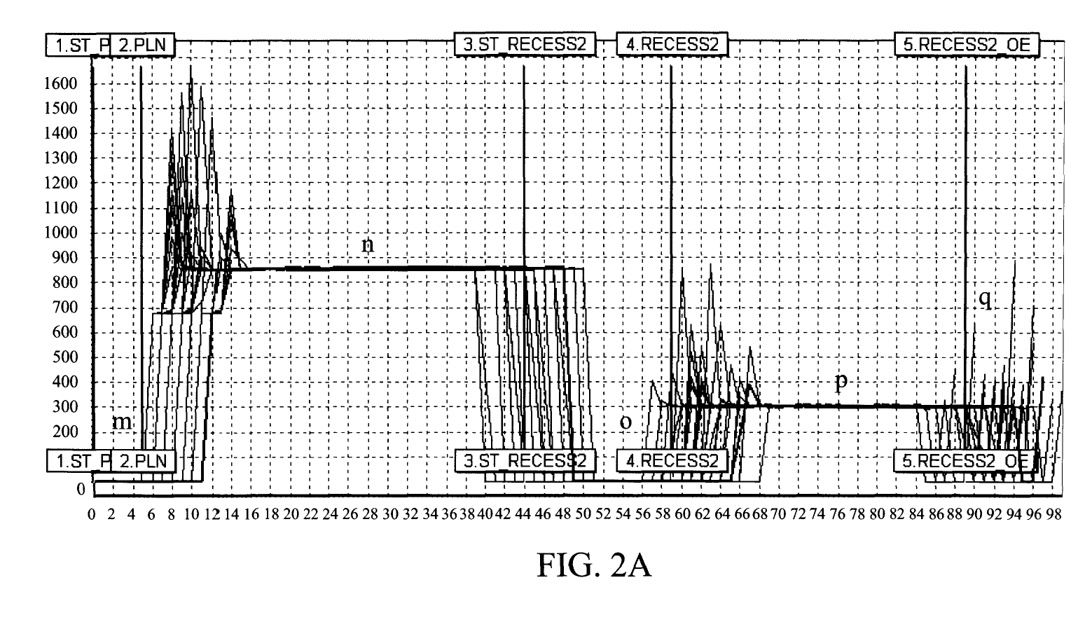

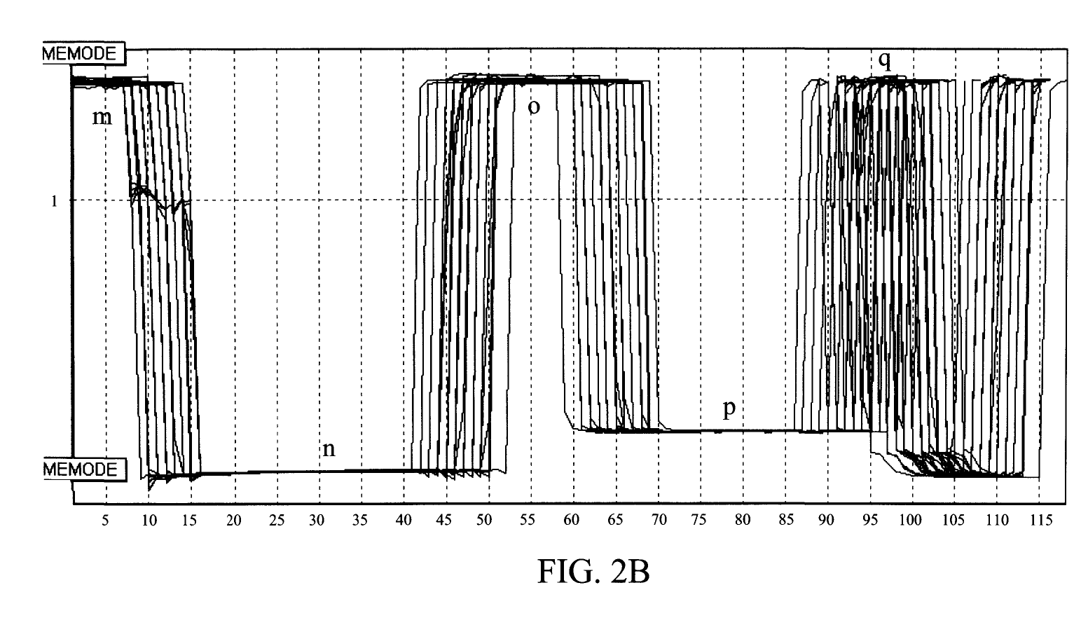

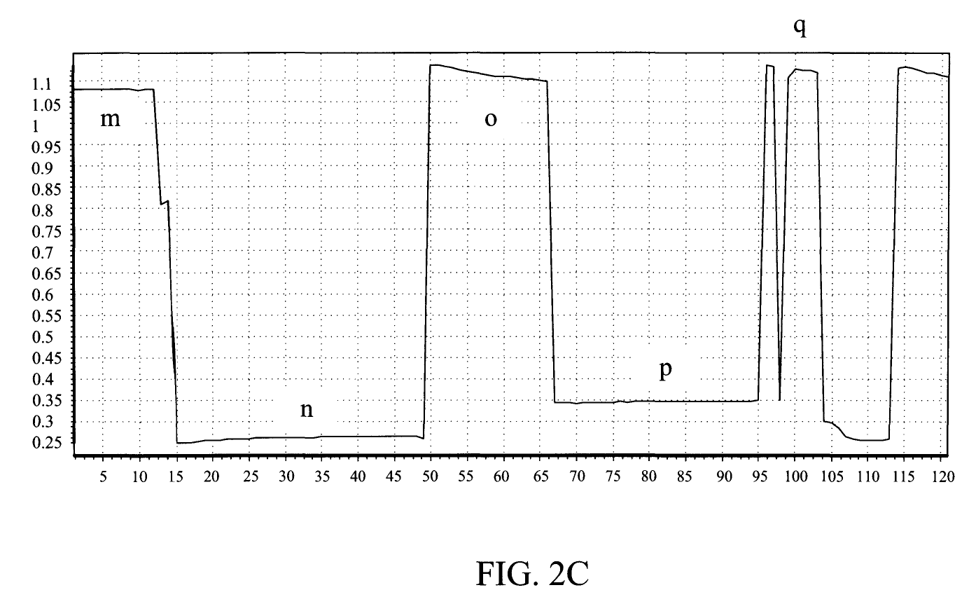

An exemplary plasma reaction will be shown to describe the features of the detection system for a plasma reaction of the invention. Please refer to FIG. 2A, which schematically illustrates power variations of plasma reactions in one embodiment. The horizontal axis represents time and the vertical axis represents plasma power. A plurality of curves is shown in the drawing and each of the curves represents a power variation of a plasma reaction.

Please refer to FIG. 2B together with FIG. 2A. FIG. 2B shows a corresponding variation of the resistance value of the sensing device 110. In real applications, a proper circuit would be connected with the sensing device 110 to output a signal in relative to the resistance value of the sensing device 110. FIG. 2A and FIG. 2B show that the resistance variation of the sensing device 110 has an opposite relationship with the power variation of a plasma reaction. That is, when the power of a plasma reaction becomes large, the light thereof would become strong as well and the resistance value of the CdS photoconductive resistance would become small correspondingly. On the contrary, when the power of a plasma reaction decrease, the light thereof would become dark and the resistance value of the CdS photoconductive resistance would reversely become large.

Please refer to FIG. 2C together with FIG. 2A, wherein FIG. 2C shows one of the curves selected from FIG. 2B. The curves shown in FIG. 2A and FIG. 2C can be respectively divided into 5 portions, including “m”, “n”, “o”, “p”, “q” along the horizontal axis. The “m” portion of FIG. 2A represents the plasma does not begin to react. Therefore, the photoconductive resistance in the detection system is in a status with a high level as shown in the corresponding “m” portion of FIG. 2C.

Next, as the plasma begins to react, the power of the plasma increases as shown in the “n” portion of FIG. 2A. The plasma glows increasingly so that the resistance value of the photoconductive resistance of the detection system decreases reversibly as shown in the “n” portion of FIG. 2C. As shown in the “o” portion of FIG. 2A, the power of the plasma reaction has been turn off so that the plasma stops glowing. Correspondingly, the resistance value of the photoconductive resistance of the detection system increases correspondingly and quickly to a high level the same as the plasma begins to react.

In the “p” portion of FIG. 2A, the plasma begins to react again and the power of the plasma in the “p” portion is smaller than the power indicated by the “n” portion of FIG. 2A. Correspondingly, the resistance value of the photoconductive resistance in the “p” portion of FIG. 2C is larger than that of the photoconductive resistance indicated by the “n” portion of FIG. 2C. More particularly, when the reaction is conducted into “q” portion, the plasma power changes quickly along the time axis. The resistance value in the “q” portion of FIG. 2C also changes reversibly and quickly. According to the above, the sensing device 110 in the detection system for plasma reactions disclosed by the subject invention can effectively, quickly, and precisely detect plasma reactions with different powers. Therefore, the detection system for plasma reactions disclosed by the subject invention is an effective monitoring tool to detect the status of the plasma reactions.

It is noted that the photoconductive resistance is configured outside an observation window of a plasma reaction chamber. The observation window is a transparent material so that the photoconductive resistance can directly detect the light variation of the plasma reaction conducted in the reaction chamber via the observation window. The sensing device of the subject invention is unnecessary to invade the reaction chamber for detecting reactions so that it can facilitate to integrate the detection system of the subject invention into any kinds of present plasma reaction equipment. The detection system of the subject invention can be in widespread use for real applications.

It is appreciated that the photoconductive resistance used in the detection system of the subject invention is only sensitive to the light variation rather than to the temperature variation of plasma reactions. Accordingly, the temperature variation would not impose any substantial influence on the photoconductive resistance used in the subject invention. No detection error would be resulted from the temperature variation.

It is appreciated that the subject invention further provides a method for detecting a plasma reaction by applying the detection system as shown in FIG. 1. The method comprises the following steps.

First, providing a sensing device 110 to a plasma reaction chamber so that the sensing device 110 can change its resistance value in response to a lightness variation during the plasma reaction.

Second, providing a signal processing device 120 to measure the resistance value of the sensing device 110 and then generate an output voltage of a signal and process the signal to indicate the status of the plasma reaction. It is noted that the sensing device 110 and the signal processing device 120 comprise all features as disclosed above. The details thereof are omitted.

In a preferred embodiment, the step of providing the signal processing device 120 to generate the signal further comprises a step of providing an offset circuit assembly 122 used for adjusting the output voltage of the signal after receiving the signal. If the signal is an analog signal, the abovementioned step further comprises a step of providing a signal converter 124 used for converting the analog signal to a digital signal. It is noted that the offset circuit assembly 122 and the signal converter 124 comprise all features as disclosed above.

Moreover, the method for detecting a plasma reaction of the subject invention further comprises the following steps: providing a database 140 for storing the signal after the signal being processed by the signal processing device. Then, an error detection device 150 is provided to connect to the database 140 for detecting the status of the plasma reaction.

In a preferred embodiment of the subject invention, the method further comprises a step of providing a signal transmission module 130, connected between the signal processing device 120 and the database 140, used for transmitting the signal from the signal processing device 120 to the database 140. It is noted that the signal transmission module 130, the database 140, and the error detection device 150 comprise all features as disclosed above. The above disclosures are incorporated herein by reference.

To sum up, the detecting system and the method for plasma reactions disclosed by the subject invention not only detect the reaction quickly, but also sensitively and precisely. Moreover, the whole detecting system only costs several thousands. Compared the cost with the optic emission spectrum sensor of the prior art, the detecting system and the method disclosed the subject invention is more cheap and can be in widespread use. Furthermore, the non-invasion feature of the detecting system of the subject invention facilitates the detecting system can be easily integrated with any present plasma reaction equipment to provide a reliable and cheap solution to the prior art.

The above examples are only intended to illustrate the principle and efficacy of the subject invention, not to limit the subject invention. Any people skilled in this field may proceed with modifications and changes to the above examples without departing from the technical principle and spirit of the subject invention. Therefore, the scope of protection of the subject invention is covered in the following claims as appended.

What is claimed is:

1. A system for detecting a plasma reaction, when the plasma reaction has a power variation, a lightness variation accompanies the power variation, the system comprising:
a sensing device, comprising a resistance, wherein the resistance will be changed in response to the lightness variation, thereby the system can detect the status of the plasma reaction.

2. The system of claim 1, wherein the sensing device is a photoconductive resistance.

3. The system of claim 2, wherein the plasma reaction is conducted in a plasma reaction chamber and the photoconductive resistance is configured outside an observation window of the plasma reaction chamber used for sensing the lightness variation.

4. The system of claim 2, wherein the photoconductive resistance is CdS.

5. The system of claim 1, further comprising a signal processing device used for generating a signal after measuring the resistance of the sensing device and processing the signal.

6. The system of claim 5, wherein the signal processing device comprises an offset circuit assembly used for adjusting an output voltage of the signal after receiving the signal.

7. The system of claim 5, wherein the signal is an analog signal and the signal processing device comprises a signal converter used for converting the analog signal to a digital signal.

8. The system of claim 5, further comprising a database used for storing the signal after the signal being processed by the signal processing device.

9. The system of claim 8, further comprising a signal transmission module, connected between the signal processing device and the database, used for transmitting the signal from the signal processing device to the database.

10. The system of claim 9, wherein the signal transmission module is an RS232 module or a TCPIP module.

11. The system of claim 8, further comprising an error detection device, connected to the database, used for detecting a status of the plasma reaction.

12. A method for detecting a plasma reaction, when the plasma reaction has a power variation, a lightness variation accompanies the power variation, the method comprising:
providing a sensing device, the sensing device comprising a resistance;
changing the resistance in response to the lightness variation;
measuring the resistance of the sensing device; and
generating a signal in response to the resistance.

13. The method of claim 12, wherein the sensing device is a photoconductive resistance.

14. The method of claim 13, wherein the plasma reaction is conducted in a plasma reaction chamber and the photoconductive resistance is configured outside an observation window of the plasma reaction chamber used for sensing the lightness variation.

15. The method of claim 13, wherein the photoconductive resistance is CdS.

16. The method of claim 12, wherein the step of measuring uses a signal processing device to generate a signal and process the signal after measuring the resistance of the sensing device.

17. The method of claim 16, wherein the step of processing the signal uses an offset circuit assembly to adjust an output voltage of the signal after receiving the signal.

18. The method of claim 16, wherein the signal is an analog signal and the method further comprises a step of providing a signal converter for converting the analog signal to a digital signal.

19. The method of claim 16, further comprising a step of providing a database for storing the signal after the signal being processed by a signal processing device.

20. The method of claim 19, further comprising a step of providing a signal transmission module, connected between the signal processing device and the database, used for transmitting the signal from the signal processing device to the database.

21. The method of claim 20, wherein the signal transmission module is an RS232 module or a TCPIP module.

22. The method of claim 19, further comprising a step of providing an error detection device, connected to the database, used for detecting the status of the plasma reaction.
